(19) United States
(12) Patent Application Publication
(10) Pub. No.: US 2024/0232694 A1
(43) Pub. Date: Jul. 11, 2024

(54) SYSTEM AND METHOD FOR OPERATIONAL ANALYSIS OF ENERGY STORAGE DEVICES

(71) Applicant: UL, LLC, Northbrook, IL (US)

(72) Inventors: Yuwei Lai, Taipei (TW); Kailu Wang, Taipei (TW); Ming-Lung Wu, Taipei (TW); Tawei Chao, Taipei (TW)

(21) Appl. No.: 18/094,106

(22) Filed: Jan. 6, 2023

(51) Int. Cl. G06N 20/00

(52) U.S. Cl. CPC G06N 20/00

(57) ABSTRACT

A device may receive a plurality of reference datasets for a machine learning model, wherein each reference dataset is indicative of a cell feature of one or more cell features, receive a first dataset based on a discharge cycle of one or more cells of a battery having an unknown operation history, determine a second dataset based on the first dataset, extract a third dataset based on applying a first model to the second dataset, extract a fourth dataset based on applying a second model to the third dataset, determine that the fourth dataset matches at least one of the plurality of reference datasets, and indicate a prior use of the battery based on the fourth dataset matching at least one of the plurality of reference datasets.

### FIELD

The present disclosure relates to the field of energy storage devices. More particularly, to operational analysis of batteries.

### BACKGROUND

Energy storage devices are commonly used for electronic devices throughout society, including for electric vehicles, powering homes, etc. Energy storage devices, such as a battery, may be reused after their first life to reduce the environmental impact of disposal and to increase the economic benefit for each battery.

### SUMMARY

Described herein are various systems, methods, computer readable media, and apparatuses for training and using machine learning models to analyze and determine matches between second use candidate battery cycling performance test results with performance test results previously acquired from other batteries with known operational histories having known abuse conditions. Once the machine learning models are trained to recognize matching analysis results, the models may be used to determine the operational history of the second use candidate battery based on the analysis matching results of the reference battery having a similar operational history. This may be valuable, for example, when the cycle performance tests of the candidate battery do not indicate the presence of any current thermal, electrical, or mechanical faults, at the time of testing, but matching performance test results of the reference battery or batteries have demonstrated an increased probability of these faults. Therefore, using a particular candidate battery with performance test results that match previously acquired performance test results indicating abuse conditions during the first life use of the battery may pose a risk of premature failure during a second life use of the candidate battery.

In various embodiments, a method includes receiving, by one or more processors of one or more computing devices, a plurality of reference datasets annotated with at least one cell feature. In various embodiments, the method includes determining, by the one or more processors, a first dataset based on a cycle of one or more cells of a battery, wherein the first dataset includes a plurality of first feature pairs indicative of an unknown operation history. In various embodiments, the method includes extracting, by the one or more processors, a second dataset based on applying a first model to the first dataset, wherein the second dataset includes a plurality of second feature pairs for the at least one cell feature. In various embodiments, the method includes extracting, by the one or more processors, a third dataset based on applying a second model to the second dataset, wherein the third dataset includes a plurality of third feature pairs. In various embodiments, the method includes determining, by the one or more processors, an operational history aspect indicative of the at least one cell feature of the battery extracted based on applying the second model and the third dataset.

In various embodiments, extracting the second dataset based on applying the first model to the first dataset further includes extracting, by the one or more processors, the plurality of second feature pairs based on a principal component analysis including an unsupervised algorithm of the first dataset for the at least one cell feature.

In various embodiments, each feature pair of the plurality of second feature pairs includes a first vector based on a respective first feature pair of the plurality of first feature pairs and a first eigenvalue corresponding to the respective first feature pair, and a second vector based on the respective first feature pair and a second eigenvalue corresponding to the respective first feature pair.

In various embodiments, extracting the third dataset based on applying the second model to the second dataset further includes: extracting, by the one or more processors, the plurality of third feature pairs based on a linear discriminant analysis including a supervised algorithm of the second dataset for the at least one cell feature.

In various embodiments, each feature pair of the plurality of third feature pairs includes: a third vector based on a respective second feature pair of the plurality of second feature pairs and a third eigenvalue corresponding to the respective second feature pair, and a fourth vector based on the respective second feature pair and a fourth eigenvalue corresponding to the respective second feature pair.

In various embodiments, each respective first feature pair of the plurality of first feature pairs includes a voltage and a capacity of the one or more cells over a voltage range of the cycle from a first voltage to a second voltage.

In various embodiments, the method further includes determining, by the one or more processors, a fourth dataset based on the first dataset. In various embodiments, the fourth dataset includes a plurality of fourth feature pairs for the at least one cell feature. In various embodiments, each respective fourth feature pair of the plurality of fourth feature pairs includes a mean voltage and a dQ-dV of the battery of the one or more cells over the voltage range of the cycle.

In various embodiments, the method further includes training, by the one or more processors, the first model and the second model based on a training dataset. In various embodiments, the method further includes training, by the one or more processors, the plurality of reference datasets based on the training dataset. In various embodiments, each reference dataset is indicative of results of a reference principal component analysis performed by the first model and a reference linear discriminate analysis performed by the second model to determine the at least one cell feature.

In various embodiments, each reference dataset of the plurality of reference datasets further includes a plurality of historical feature pairs annotated with a cell feature of the at least one cell feature.

In various embodiments, the at least one cell feature includes a normal operation. In various embodiments, the at least one cell feature includes an ambient temperature. In various embodiments, the at least one cell feature includes a working voltage range. In various embodiments, the at least one cell feature includes a high-rate discharge parameter. In various embodiments, the at least one cell feature includes an abnormal operation voltage range. In various embodiments, the at least one cell feature includes at least one of a normal operation, an ambient temperature, a working voltage range, a high-rate discharge parameter, and an abnormal operation voltage range.

In various embodiments, a system includes at least one processor and a non-transitory computer readable medium having instructions stored thereon that, when executed by the at least one processor, cause the system to perform operations including: receive a plurality of reference datasets annotated with at least one cell feature. In various embodiments, the system may perform operations including determine a first dataset based on a cycle of one or more cells of a battery. In various embodiments, the first dataset includes a plurality of first feature pairs indicative of an unknown operation history. In various embodiments, the system may perform operations including extract a second dataset based on applying a first model to the first dataset. In various embodiments, the second dataset includes a plurality of second feature pairs for the at least one cell feature. In various embodiments, the system may perform operations including extract a third dataset based on applying a second model to the second dataset. In various embodiments, the third dataset includes a plurality of third feature pairs. In various embodiments, the system may perform operations including determine an operational history aspect indicative of the at least one cell feature of the battery extracted based on applying the second model and the third dataset. In various embodiments, the at least one processor is further configured to send data to a display indicative of the operational history aspect of the battery.

In various embodiments, the data sent to the display is indicative of the third dataset matching the plurality of reference datasets.

In various embodiments, the data sent to the display further includes scatter plot data configured to cause the display to show a representation of the third dataset. In various embodiments, the third dataset is indicative of a linear discriminant analysis including a supervised algorithm for the at least one cell feature.

In various embodiments, the system further performs operations including determine a fourth dataset based on the first dataset. In various embodiments, the fourth dataset includes a plurality of fourth feature pairs for the at least one cell feature. In various embodiments, each respective first feature pair of the plurality of first feature pairs includes a voltage and a capacity of the one or more cells over a voltage range of the cycle from a first voltage to a second voltage. In various embodiments, each respective fourth feature pair of the plurality of fourth feature pairs includes a mean voltage and a dQ-dV of the battery of the one or more cells over the voltage range of the cycle.

In various embodiments, each respective second feature pair of the plurality of second feature pairs includes a first vector based on a respective first feature pair of the plurality of first feature pairs and a first eigenvalue corresponding to the respective first feature pair, and a second vector based on the respective first feature pair and a second eigenvalue corresponding to the respective first feature pair. In various embodiments, each respective third feature pair of the plurality of third feature pairs includes: a third vector based on a respective second feature pair of the plurality of second feature pairs and a third eigenvalue corresponding to the respective second feature pair, and a fourth vector based on the respective second feature pair and a fourth eigenvalue corresponding to the respective second feature pair.

In various embodiments, the at least one cell feature includes a normal operation parameter, an ambient temperature, a working voltage range, a high-rate discharge parameter, and an abnormal operation voltage range.

In various embodiments, the system further performs operations including train the first model and the second model based on a training dataset; and train the plurality of reference datasets based on the training dataset. In various embodiments, each reference dataset is indicative of results of a reference principal component analysis performed by the first model and a reference linear discriminant analysis performed by the second model to determine the at least one cell feature.

In various embodiments, a non-transitory computer readable medium having instructions stored thereon that, when executed by a computing device, cause the computing device to perform operations including: receive a plurality of reference datasets annotated with a cell feature of at least one cell feature; determine a first dataset based on a cycle of one or more cells of a battery, wherein the first dataset includes a plurality of first feature pairs indicative of an unknown operation history; extract a second dataset including a plurality of second feature pairs based on applying a first model to the first dataset, wherein the plurality of second feature pairs includes: a first vector based on a respective second feature pair of the plurality of second feature pairs and a first eigenvalue corresponding to the respective second feature pair, and a second vector based on the respective second feature pair and a second eigenvalue corresponding to the respective second feature pair; extract a third dataset including a plurality of third feature pairs based on applying a second model to the second dataset, wherein the plurality of third feature pairs includes: a third vector based on a respective third feature pair of the plurality of third feature pairs and a third eigenvalue corresponding to the respective third feature pair, and a fourth vector based on the respective third feature pair and a fourth eigenvalue corresponding to the respective third feature pair; and determine an operational history aspect of the battery extracted based on applying the second model and the third dataset; wherein the at least one cell feature includes: a normal operation, an ambient temperature, a working voltage range, a high-rate discharge parameter, and an abnormal operation voltage range parameter.

In various embodiments, the computing device performs operations further including determine a fourth dataset based on the first dataset. In various embodiments, the fourth dataset includes a plurality of fourth feature pairs for a respective cell feature. In various embodiments, each of the plurality of first feature pairs includes a voltage and a capacity of the one or more cells over a voltage range of the cycle from a first voltage to a second voltage. In various embodiments, each of the plurality of fourth feature pairs includes a mean voltage and a dQ-dV of the battery of the one or more cells over the voltage range of the cycle.

In various embodiments, the computer device further performs operations including train the first model and the second model based on a training dataset, and train the plurality of reference datasets based on the training dataset. In various embodiments, each reference dataset is indicative of results of a reference principal component analysis performed by the first model and a reference linear discriminate analysis performed by the second model to determine the at least one cell feature.

### BRIEF DESCRIPTION OF THE DRAWINGS

Various embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 illustrates a flow diagram of a battery life cycle, according to various embodiments.

FIG. 2 illustrates a method for determining an unknown operational history of the battery, according to various embodiments.

FIG. 3 illustrates a process for training a machine learning model, according to various embodiments.

FIG. 4 illustrates example graphical representations of performance testing of a battery, according to various embodiments.

FIGS. 5A-5D illustrate example graphical representations based on application of the machine learning model, according to various embodiments.

FIGS. 6A-6C illustrates example graphical representations of the one or more cell features of the battery, according to various embodiments.

FIG. 7 is a block diagram depicting a computer-based system and platform, according to various embodiments.

FIG. 8 is a block diagram depicting another computer-based system and platform, according to various embodiments.

### DETAILED DESCRIPTION

Various detailed embodiments of the present disclosure, taken in conjunction with the accompanying figures, are disclosed herein; however, it is to be understood that the disclosed embodiments are merely illustrative. In addition, each of the examples given in connection with the various embodiments of the present disclosure is intended to be illustrative, and not restrictive.

Energy storage devices, such as a battery, may be reused after their first life to reduce the environmental impact of disposal and to increase the economic benefit for each battery. A candidate battery for second use is assessed using various tests and methods to determine the condition of the one or more cells of the battery. Typically, various cycling performance tests are applied to the candidate battery to determine the capacity and output capabilities. The results of these tests may be used to determine whether there are any thermal, electrical, or mechanical defects in the battery. However, an operational history of a battery may be unknown unless the candidate battery was under the control of the tester. Accordingly, although performance testing can detect present battery failure based on exceeding a specified threshold, performance testing alone cannot determine an operational life history of a candidate battery or whether the candidate battery faced an abuse condition during its operation.

Described herein are systems, devices, computing devices, server-based networks, etc., including a processor, and a non-transitory computer readable media having stored thereon instructions executable by the processor to cause the system to perform various operations. In various embodiments, the system may include a machine learning model stored on the computer readable media that applies the machine learning model to the performance testing dataset of a candidate battery to determine an operational history of the candidate battery and to determine the one or more cell features of the candidate battery corresponding to an abuse condition during the first life of the candidate battery. In various embodiments, the system can train a machine learning model to identify an abuse history of a battery based on dataset corresponding to performance testing results of reference batteries and applying the machine learning model to determine an operational history of a candidate battery based on performance testing of the candidate battery. In various embodiments, training the machine learning model includes iteratively determining a reference dataset based on performance testing of one or more batteries having known operational histories to obtain data corresponding to one or more cell features. In various embodiments, the system can apply the machine learning model to datasets corresponding to the performance testing results of the battery to determine an output indicative of the operational history of the battery based on a comparison between the reference dataset and the performance test data. In other words, the machine learning model may be trained to predict or determine aspects of an operational history and use of a battery that has an unknown operational history. Since used battery candidates (e.g., second use battery) can have applications after their first use, it may be desirable to determine the one or more cell features of the used battery candidate based on the operational use history to determine whether the used battery candidate experienced an abuse condition during its first use operation, and therefore determine whether the used battery is appropriate for a second use operation. Abuse conditions during operation of the first use battery may include any of a plurality of conditions exceeding a specified threshold including, but not limited to, charge/discharge rate, temperature range, ambient temperature range, high-rate discharge parameter, working voltage range, abnormal operation voltage range, other conditions, or combinations thereof. By matching the candidate battery performance test data to the reference dataset, a testing entity may be able to certify the candidate battery is suitable or unsuitable for a second use or for a particular second use purpose. Various embodiments herein include training the machine learning model to predict or determine matches of the performance test results between the candidate battery and one or more reference batteries using datasets related to specific analyses performed on the batteries. The datasets referred to herein include data that corresponds to an operational history aspect of the battery. As such, the various embodiments described herein provide for comparing the operational history aspects to determine a similarity between the candidate battery having an unknown operational history and reference batteries having one or more known operational history aspects. The operational history aspects may be representative of whether the candidate battery includes one or more cell features indicative of whether the candidate battery experienced abuse during the first use operation of the candidate battery.

In various embodiments, the performance test dataset may be obtained based on a cycle of the battery. In various embodiments, the performance test dataset may be obtained based on a cycle of the one or more cells of the battery. In various embodiments, the performance test data may include a data corresponding to a capacity-voltage of the battery. In various embodiments, the performance test data may include a data corresponding to a temperature-voltage of the battery. In various embodiments, the performance test data may include data corresponding to an incremental capacity analysis (e.g., dQ/dV curve) of the battery. In various embodiments, the performance test data may include data corresponding to any of a plurality of conditions including ambient temperature, over charge/discharge, discharge depth (SOC range), mechanical abuse (drop, pressed, vibration), electric abuse (external short-circuit), cycling, storage, other factors, or any combinations thereof.

In various embodiments, the machine learning model may obtain the dataset corresponding to the performance test results. In various embodiments, the machine learning model may extract one or more cell features from the dataset. In various embodiments, the machine learning model extracting the plurality of feature pairs from the performance test dataset includes performing a dimension reduction of a performance test dataset.

In various embodiments, the machine learning model may be a machine learning engine including one or more machine learning models. Accordingly, in various embodiments, the machine learning engine may apply the one or more models to the dataset corresponding to the performance test results to perform extract the one or more cell features by performing a dimension reduction to the dataset to determine the one or more cell features of the battery. In various embodiments, the machine learning engine may include a first machine learning model and a second machine learning model. In various embodiments, the first machine learning model may perform a first component analysis and the second machine learning model may further perform a second component analysis. In various embodiments, the first component analysis includes performing a dimension reduction to the performance test dataset. The dimension reduction includes extracting variables (i.e., feature pairs) from the performance test dataset corresponding to the one or more cell features, thereby reducing the number of variables compared to the performance test dataset. In various embodiments, the second component analysis includes performing a further dimension reduction to extract variables corresponding to the one or more cell features. In various embodiments, the second component analysis may be performed on the performance test dataset. In various embodiments, the second component analysis may be performed on the output of the first component analysis by the first machine learning model. In other words, in various embodiments, the dimension reduction includes extracting variables from the output by the first machine learning model based on the first component analysis and thereby further reducing the number of variables (i.e., feature pairs). For example, the performance test results may generate a dataset including 143 variables, the first component analysis extracts 14 variables from that dataset, and the second component analysis further extracts 2 variables from the 14 variables output by the first machine learning model.

In various embodiments, the first component analysis may be an unsupervised principal component analysis (PCA) algorithm. The unsupervised PCA algorithm produces non-labeled data indicating a maximum variance among all data from the unsupervised PCA algorithm. In various embodiments, the second component analysis may be a supervised linear discriminant analysis (LDA) algorithm. The supervised LDA algorithm provides labeled data indicating a maximum variance between groups and a minimum variance within a group. For example, an incremental capacity analysis for a candidate battery may produce 81 variables in a voltage range of 3.5025-3.9025 V with an interval of 0.005 V, the first component analysis performs a dimension reduction to output ten variables, and the second component analysis performs a further dimension reduction to output two variables. In various embodiments, the second component analysis model may be a supervised support vector machine (SVM) algorithm.

In various embodiments, the machine learning model may perform a classification of the dataset output by a first component analysis, the dataset output by the second component analysis, or combinations thereof. In various embodiments, the classification may include a decision tree method. In various embodiments, the machine learning model may determine the dataset output by the machine learning model corresponds to a high-rate discharge group and may determine an abuse condition of the battery during the first use operation. In various embodiments, the dataset output by the machine learning model may correspond to an over-charge of the candidate battery during its first use operational history. In various embodiments, the data output by the machine learning model for the candidate battery may correspond to an over-discharge of the candidate battery during its first use operational history. For example, if the data output by the machine learning model for the candidate battery does not meet a threshold for the high-rate discharge group, the over-charge group, or the over-discharge group, then the machine learning model may categorize the candidate battery in the normal group indicating the performance test data of the candidate battery does not match the performance test data of the one or more reference batteries. The embodiments described herein may, therefore, provide cost savings and time savings to the entity testing candidate batteries for a second use. The embodiments described herein represent an improvement over methods where the incremental capacity analysis may detect a presently existing thermal, electrical, or mechanical defect in the battery. The embodiments described herein represent an improvement over methods where the machine learning model applies a single stage of either the unsupervised PCA analysis or the supervised LDA analysis to the performance test dataset to determine whether the candidate battery exceeded an ambient temperature or a discharge depth. Thus, the embodiments described herein represent an improvement in the accuracy of determining whether the candidate battery exceeded an ambient temperature threshold, or a discharge path, compared to methods where only a single stage model is applied to the performance test dataset. In various embodiments, the machine learning model can determine a discharge C-rate and over-charge/discharge group classification for the battery with 77% accuracy. In various embodiments, the embodiments described herein can determine a high-rate discharge with 92% accuracy, an over-discharge with 93% accuracy, and an over-charge with 99% accuracy.

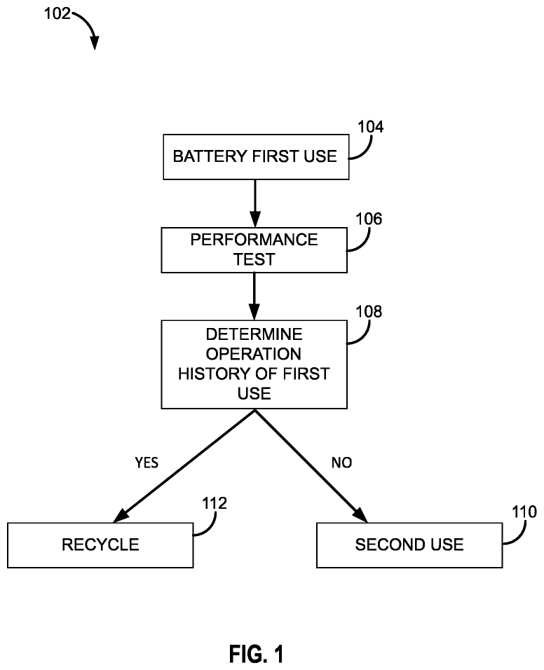

FIG. 1 illustrates a flow diagram of a battery life cycle 102, according to various embodiments. At 104, a new battery undergoes a first use. The first use can include multiple charge/discharge cycles and various operational conditions.

At 106, an entity may perform a performance test on the battery to generate a dataset corresponding to results indicative of an operational history of the battery. The dataset may include one or more object instances corresponding to any of a plurality of cell features including, but not limited to, normal operation, ambient temperature, over charge/discharge, discharge depth (SOC range), mechanical abuse (e.g., drop, pressed, vibration), electrical abuse (e.g., external short-circuit), cycling, storage conditions, other factors, or any combinations thereof. In various embodiments, the dataset may include data corresponding to a normal operational history of the battery. In various embodiments, the dataset may include data corresponding to a first use battery (e.g., fresh battery). In various embodiments, the performance test may generate a dQ/dV curve indicative of one or more cell features corresponding to a condition of the battery (or the one or more cells of the battery). In various embodiments, the performance test dataset may include a capacity-voltage of the battery, an incremental capacity analysis (dQ/dV) of the battery, a temperature-voltage of the battery, other features of the battery, or any combinations thereof.

In various embodiments, performance testing includes cycling power in the battery. In various embodiments, the performance testing may include a charge cycle, a discharge cycle, a rest cycle for a period of time, or any combinations thereof. In various embodiments, performance testing of the battery may include at least one cycle. In various embodiments, performance testing may include a specific number of cycles. In various embodiments, performance testing may include a plurality of cycles.

At 108, the system may apply the machine learning model to the dataset corresponding to the performance test results to determine an operational history of the battery. In various embodiments, the machine learning model obtains the performance test dataset and determines the one or more cell features of the candidate second use battery indicative of an operational history aspect of the candidate battery. In various embodiments, the performance test dataset may indicate a normal operational history of the battery and the battery may be a candidate for a second use based on the determination by the machine learning model and a correlation between the performance test data of the reference battery and the candidate battery. In various embodiments, the performance test dataset and the machine learning model may determine an abuse condition based on a correlation between the performance test dataset of the reference battery (or batteries) and the candidate battery indicative of the one or more cell features.

At 110, the system may determine the candidate battery is viable as a second use battery based on application of the machine learning model. In various embodiments, the system may determine the candidate battery is eligible for a specific second use based on application of the machine learning model.

At 112, the system may determine the candidate battery is not viable as a second use battery and may reject the battery for a second use. In various embodiments, rejection of the battery for a second results in the second battery being discarded. For example, in various embodiments, the battery may be recycled.

In various embodiments, after a second use of a battery, steps at 106 and 108 may be repeated for the battery. That is, battery performance testing and application of the machine learning model to the dataset corresponding to the performance test after the second use to determine if the battery is viable for a third use or should be recycled. In various embodiments, this process may also be repeated after a third use, fourth use, etc. of a battery. In this way, a battery may be tested multiple times, potential abuse of the battery identified, and a designation made whether the battery should continue to be used or recycled.

A system for predicting an operational history of a battery using a machine learning model may include a computing device. The computing device may include one or more processors and a non-transitory computer readable medium. The non-transitory computer readable medium may have instructions stored thereon that are executable by the one or more processors to cause the computing device to perform various operations in accordance with the present disclosure. In various embodiments, the computer readable medium may include the machine learning model to predict the operational history of the battery based on the performance test. In various embodiments, the computing device may perform the performance test as will be further described below.

In various embodiments, the computing device may include a display. In various embodiments, the at least one processor may be configured to send data to the display indicative of the operational history aspect of the battery. In various embodiments, the data sent to the display may include scatter plot data configured to show a representation of one or more variables (e.g., feature values) indicative of performance testing, component analysis results based on application of one or more component analysis algorithms, or any combinations thereof.

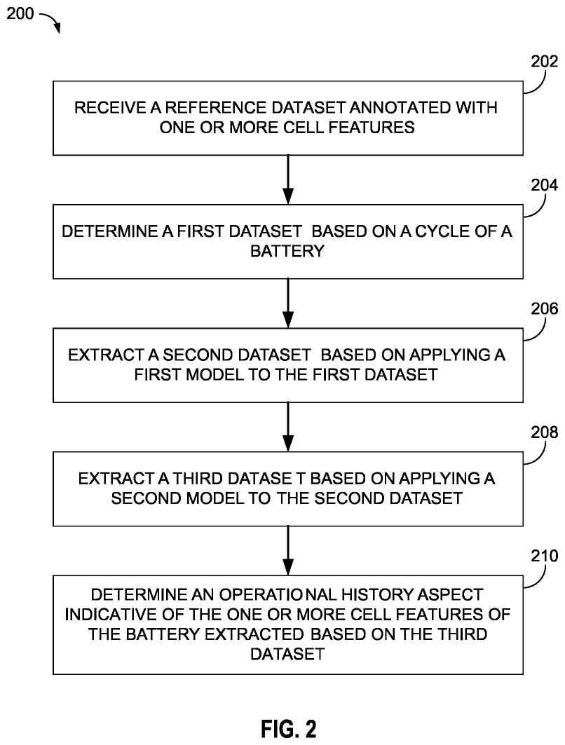

FIG. 2 illustrates a method 200 for determining an unknown operational history of the battery, according to various embodiments. At 202, the method 200 includes receiving a reference dataset annotated with one or more cell features. The reference dataset includes data corresponding to performance test data indicating one or more cell features. In various embodiments, the reference dataset may be based on an operational history of each reference battery of the one or more reference batteries. In various embodiments, the reference dataset may be used by the machine learning model to determine an operational history of the candidate battery as will be further described herein. In various embodiments, the reference dataset may be used as training data to train the machine learning model. In various embodiments, the reference dataset may include one or more datasets corresponding to the one or more cell features for each reference battery of the one or more reference batteries. In various embodiments, the reference dataset may include data corresponding to a normal operational history, abuse condition operational history, or any combinations thereof for each reference battery of the one or more reference batteries.

The reference dataset may include a plurality of object instances. In various embodiments, each object instance of the plurality of object instances may correspond to a capacity-voltage (Q-V), an incremental capacity (dQ-dV), a temperature-voltage (T-V), or combinations thereof of the reference battery. In various embodiments, the reference dataset may include an annotation corresponding to one or more cell features. In various embodiments, each object instance pair may include an annotation corresponding to the one or more cell features. For example, a particular object instance of the reference dataset may include an annotation indicating an over charge/discharge abuse condition operational history based on the performance test data of the reference battery. In various embodiments, each respective first feature pair of the plurality of first feature pairs comprises a voltage and a capacity of the one or more cells over a voltage range of the cycle from a first voltage to a second voltage.

At 204, the method 200 includes determining a first dataset based on a cycle of a battery. The first dataset may include one or more object instances based on the performance test of the battery. In various embodiments, the first dataset may be based on cycling the one or more cells of the battery. In various embodiments, each object instance of the plurality of object instances may correspond to a capacity-voltage (Q-V) of the battery, an incremental capacity (dQ-dV) of the battery, a temperature-voltage (T-V) of the battery, or combinations thereof.

At 206, the method 200 includes extracting a second dataset based on applying a first model to the first dataset. In various embodiments, the second dataset may include variables related to the first dataset and/or the cycle of the battery, and the variables may be or may include a plurality of second feature pairs for the one or more cell features. In various embodiments, the plurality of second feature pairs may be a plurality of object instances. In various embodiments, the plurality of second feature pairs extracted from the first dataset may correspond to a dimension reduction of the first dataset to determine an operational history of the battery. In various embodiments, the first model may be an unsupervised PCA model. In various embodiments, the unsupervised PCA model may include receiving non-labeled data corresponding to the performance test data of the battery. In various embodiments, the unsupervised PCA model may include determining a maximum variance among all data of the first dataset for each of the one or more cell features.

In various embodiments, extracting the second dataset based on applying the first model to the first dataset further includes extracting the plurality of second feature pairs based on a principal component analysis of the first dataset for the one or more cell features. In various embodiments, the principal component analysis includes applying an unsupervised algorithm to the first dataset to determine the plurality of feature pairs indicative of the one or more cell features. In various embodiments, each feature pair of the plurality of feature pairs includes a first vector value and a second vector value. In various embodiments, the first vector value may be based on a respective first feature pair of the first dataset and a first eigenvalue corresponding to the respective first feature pair. In various embodiments, the second vector value may be based on a respective first feature pair and a second eigenvalue corresponding to the respective first feature pair.

At 208, the method 200 includes extracting a third dataset based on applying a second model to the second dataset. In various embodiments, the third dataset includes one or more object instances (i.e., feature pairs) corresponding to a further dimension reduction of the second dataset to determine an operational history of the battery. The second model includes a supervised LDA model. In various embodiments, the second model includes a supervised SVM model. In various embodiments, the supervised LDA model may include receiving the output data from the first model and determining a maximum variance between groups of data corresponding to the one or more cell features. In various embodiments, the supervised LDA model may include receiving the output data from the first model and determining a minimum variance between groups of data corresponding to the one or more cell feature. The second model may be trained using the reference dataset(s) with the annotated one or more cell features. In other words, the second model may be trained to recognize cell features in a dataset based on training using the received dataset(s) of 202.

In various embodiments, extracting the third dataset further includes extracting the plurality of third feature pairs based on a linear discriminant analysis. In various embodiments, the linear discriminant analysis includes a supervised algorithm of the second dataset for the one or more cell features. In various embodiments, each feature pair of the plurality of feature pairs includes a third vector and a fourth vector. In various embodiments, the third vector may be based on a respective second feature pair of the plurality of second feature pairs and a third eigenvalue corresponding to the respective second feature pair. In various embodiments, the fourth vector may be based on the respective second feature pair and a fourth eigenvalue corresponding to the respective second feature pair.

At 210, the method 200 includes determining an operational history aspect indicative of the one or more cell features of the battery extracted based on the third dataset. In various embodiments, the operational history aspect includes any of a plurality of aspects including, but not limited to, normal operation, ambient temperature, over charge/discharge, discharge depth (SOC range), mechanical abuse (e.g., drop, pressed, vibration), electric abuse (e.g., external short-circuit), cycling, storage, normal operation parameter, other aspects, or any combinations thereof. In various embodiments, determining the operational history aspect includes the machine learning model comparing the third dataset to the reference dataset and the machine learning model determining a probability of an abuse condition for the candidate battery based on a correlation between the third dataset and the reference dataset.

In various embodiments, the method 200 further includes determining a fourth dataset based on the first dataset, wherein the fourth dataset comprises a plurality of fourth feature pairs for the one or more cell features. In various embodiments, each respective fourth feature pair of the plurality of fourth feature pairs comprises a mean voltage and a dQ-dV of the battery of the one or more cells over the voltage range of the cycle.

In various embodiments, the method 200 further includes training, by the one or more processors, the first model and the second model based on a training dataset. In various embodiments, the method 200 further includes training the plurality of reference datasets based on the training dataset. In various embodiments, each reference dataset is indicative of results of a reference principal component analysis performed by the first model and a reference linear discriminant analysis performed by the second model to determine the one or more cell features. In various embodiments, each reference dataset of the plurality of reference datasets further comprises a plurality of historical feature pairs annotated with a cell feature of the one or more cell features.

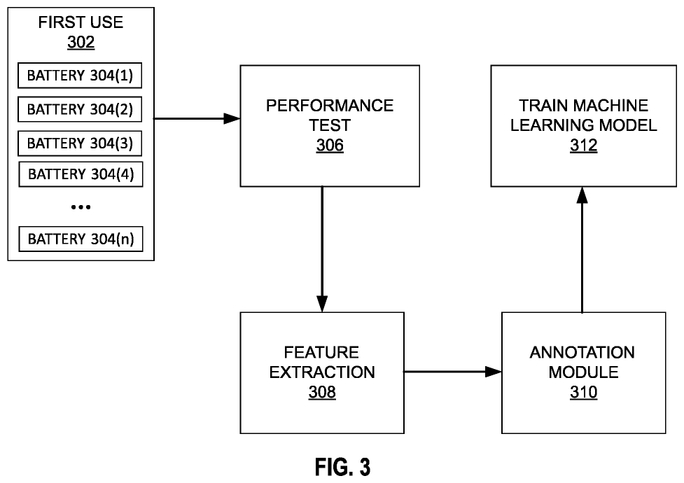

FIG. 3 illustrates a process 300 for training a machine learning model to determine the one or more cell features of a battery, according to various embodiments. In various embodiments, a server computer system may include the machine learning model. In various embodiments, the machine learning model may train the machine learning model to predict an abuse condition in the candidate battery having an unknown operational history as will be further described below. The machine learning model receives a performance test dataset corresponding to the operational history of a reference battery. The machine learning model receives the performance test dataset and extracts features from the dataset corresponding to one or more cell features based on the known operating history of the reference battery. In various embodiments, the machine learning model may further annotate the one or more object instances of the dataset based on the one or more cell features of the reference battery. In various embodiments, the machine learning model may include one or more algorithms and the machine learning model may train the one or more algorithms based on the extracted features. For example, a machine learning model may receive a dataset from the performance test of a reference battery and determine data features (i.e., object instance pairs) from the dataset to train the machine learning model for subsequent comparison of a candidate battery with the reference battery.

At 302, a reference battery is operated for a first use (i.e., new battery). The reference battery is operated under known or controlled conditions to provide a reference operational history similar to an operational history of a real-life first use battery. The operational characteristics of the battery are indicative of the one or more cell features associated with a normal condition or an abuse condition. In various embodiments, the one or more cell features of the battery may include, but are not limited to, ambient temperature indication, over charge/discharge, discharge depth (SOC range), mechanical abuse (drop, pressed, vibration), electric abuse (external short-circuit), cycling, storage, other factors, or any combinations thereof. In various embodiments, the battery may be a plurality of batteries 304(1)-304(n). In various embodiments, each battery of the plurality of batteries 304(1)-304(n) may include the reference operational history indicative of the one or more cell features corresponding to an abuse condition or a normal condition.

At 306, a performance test is performed on the reference battery. The performance test measures the operational characteristics of the reference battery and provides a dataset (i.e., performance test dataset) corresponding to the one or more cell features of the reference battery. The dataset includes a plurality of object instances indicative of the one or more cell features. The one or more cell features correspond to a condition of the battery including an abuse condition or a normal condition. In various embodiments, each object instance may be a data pair including values corresponding to measured characteristics of the battery. For example, in various embodiments, each object instance may be a data pair corresponding to a capacity and a voltage of the battery during the charge cycle.

In various embodiments, the performance test may test one or more cells of a battery. For example, a battery may include a plurality of cells and the performance test is performed on a single cell. In another example, the performance test may test all the cells of the battery individually or collectively. For example, when tested individually, each cell is tested separately to generate multiple datasets of voltage and capacity. In another example, when tested collectively, all cells are tested under series and parallel connection to general one dataset of voltage and capacity. In various embodiments, the performance test may be performed on the battery before the cycle, during the cycle, between cycles, after the cycle, or any combinations thereof. In various embodiments, the cycle for the battery may include a charge cycle, a discharge cycle, a rest cycle for a period of time, or combinations thereof. In various embodiments, the cycle may include one cycle. In various embodiments, the cycle may include a plurality of cycles.

In various embodiments, the performance test may be measured by one or more measuring devices which detect the operational characteristics of the battery. In various embodiments, the one or more measuring devices may be configured to detect any of a plurality of operational characteristics including, but not limited to, a voltage, current, impedance, resistance, capacitance, temperature, other characteristics, or any combinations thereof. In various embodiments, the server computer system may control the measurement and testing of the reference battery during the performance test. In various embodiments, the server computing system may be electrically communicable with the one or more measuring devices. Consequently, in various embodiments, the server computer system may receive electronic signals corresponding to the measured operational characteristics of the battery from each of the one or more measuring devices.

At 308, features are extracted from the performance test dataset corresponding to the one or more cell features. The one or more cell features are extracted from the performance test dataset based on the operational history of the reference battery. In various embodiments, extracting the one or more cell features may include identifying one or more object instances from the plurality of object instances in the dataset indicative of the one or more cell features. For example, the dataset may include a plurality of object instances corresponding to a Q-V curve of the reference battery and one or more object instances may be identified based on a comparison of the dataset to other datasets indicative of a normal operating history. In various embodiments, the feature extraction is based on a comparison between the performance test dataset and a dataset of a battery having a normal operation history. In various embodiments, the feature extraction is based on a comparison between the performance test dataset and a dataset having a similar operation history.

In various embodiments, the feature extractions may include an incremental capacity analysis of the performance test dataset. In various embodiments, the performance test dataset may include data corresponding to the incremental capacity analysis. In various embodiments, the feature extraction may include performing a dimension reduction on the performance test dataset. In various embodiments, the feature extraction may include performing a first dimension reduction and a second dimension reduction. In various embodiments, the first dimension reduction analyzes the dataset using an unsupervised PCA model to produce one or more variables indicative of the one or more cell features. In various embodiments, the second dimension reduction analyzes the dataset produced by the first dimension reduction using a supervised LDA model to identify one or more variables indicative of the one or more cell features. In various embodiments, the second dimension reduction analyzes the dataset produced by the first dimension reduction using a supervised SVM model to identify one or more variables indicative of the one or more cell features.

In various embodiments, the machine learning model may extract the one or more object instances from the dataset. For example, in various embodiments, the machine learning model may perform a comparison between the performance test dataset and the dataset of a battery having a normal condition operational history to identify one or more object instances from the performance test dataset indicative of an overcharge condition during the first use of the battery. In various embodiments, the performance test may be performed by a first computing device and a second computing device may receive the performance test dataset from the first computing device and perform a feature extraction on the performance test dataset.

At 310, the performance test dataset may be annotated with the one or more cell features corresponding to an operating condition of the reference battery. In various embodiments, each object instance of the plurality of object instances may be annotated with the on or more cell features based on the operation history of the battery.

At 312, a reference dataset annotated with the one or more cell features may be used to train the machine learning model. In various embodiments, the reference dataset may be stored in a data store accessible by the machine learning model. In various embodiments, the machine learning model may include a first model. In various embodiments, the first model may an unsupervised PCA analysis to perform a dimension reduction and to reduce the number of variables from the performance test dataset. In various embodiments, the machine learning model may further include a second model. In various embodiments, the second model may be a supervised LDA analysis to further perform a dimension reduction. In other embodiments, the second model may be a supervised SVM analysis to further perform the dimension reduction. In various embodiments, the reference dataset may be used to train the first model and the second model. In various embodiments, the reference dataset may be a first reference dataset and the machine learning model may further include a second reference dataset. Consequently, in various embodiments, the first reference dataset may be added to the data of the second reference dataset to train the machine learning model.

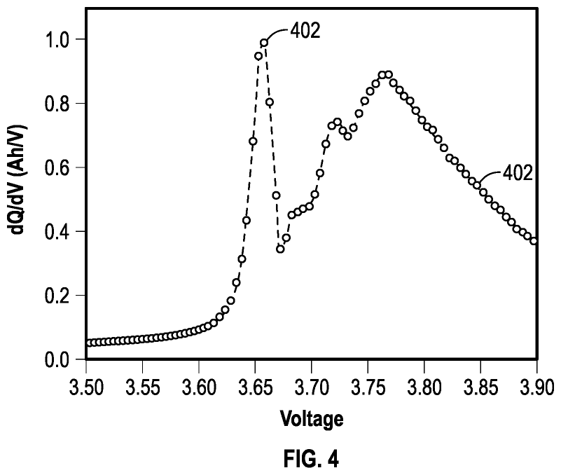

FIG. 4 illustrates a graph of a test of a battery, according to various embodiments. During the performance test, the operational characteristics of the battery are measured and used to form the performance test dataset. In various embodiments, the battery performance test may measure any of a plurality of operation characteristics including, but not limited to, temperature, capacitance, voltage, dQ, dV, other factors, or any combinations thereof. In various embodiments, the battery performance test may produce data corresponding to the capacitance and voltage (Q-V curve) of the battery at a predetermined interval over a voltage range. In various embodiments, the battery performance test may produce data corresponding to the incremental capacity analysis (dQ/dV) of the battery at predetermined intervals over the voltage range. In various embodiments, the data from the performance test may include a plurality of object instances 402 corresponding to the incremental capacity analysis of the battery at the predetermined interval for the voltage range. For example, the performance test may measure 81 variables (dQ/dV values) in the voltage range of 3.5025-3.9025 V with an interval of 0.005V.

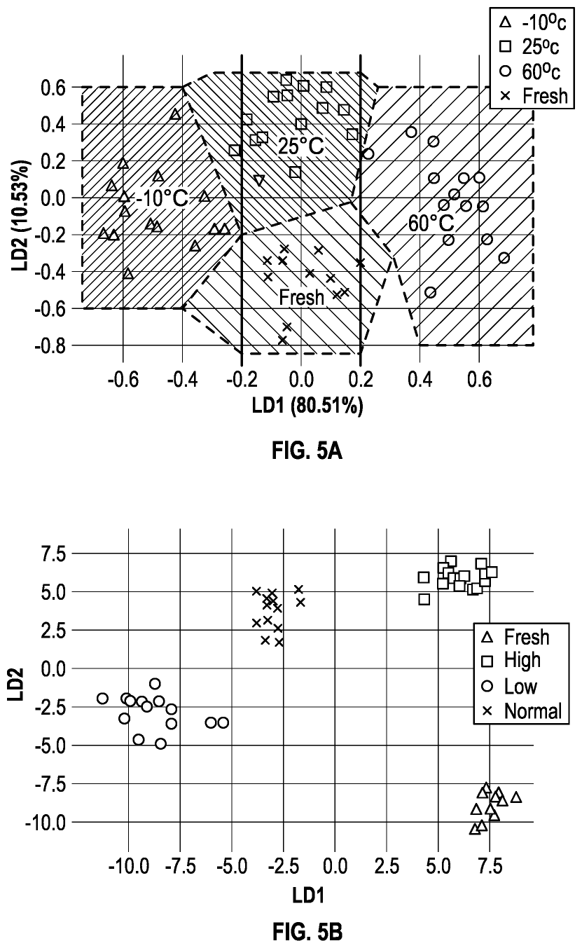

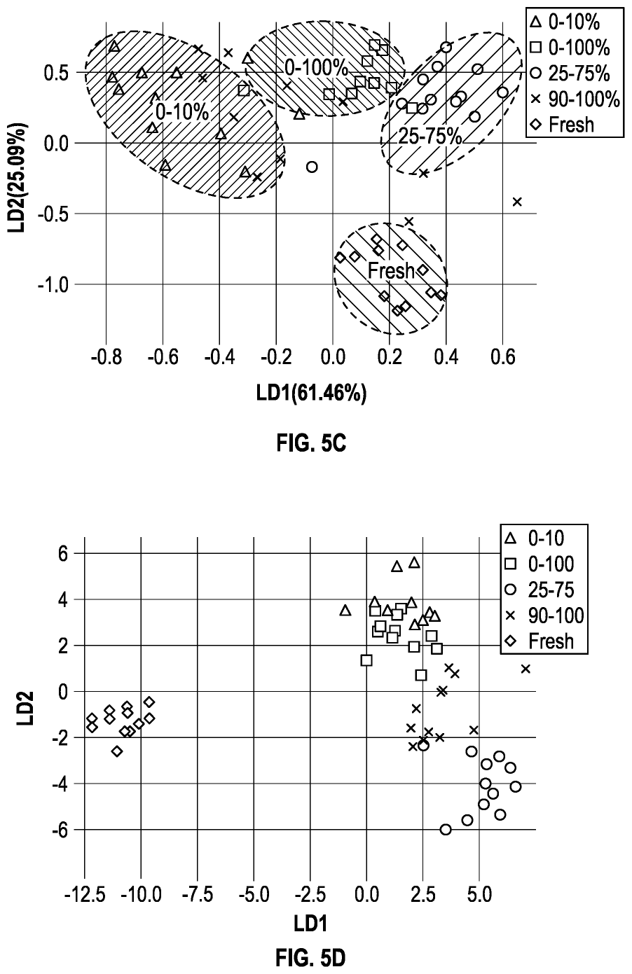

FIGS. 5A-5D illustrate example graphical representations based on application of the machine learning model, according to various embodiments. Reference will be made to FIGS. 5A-5D collectively unless specific reference is made otherwise.

In various embodiments, a system may obtain a dataset corresponding to the performance test results of the battery. The system applies the machine learning model to the dataset to determine the one or more cell features. In various embodiments, the system may apply a first machine learning model to the dataset to extract one or more variables corresponding to one or more cell features. Furthermore, in various embodiments, the first machine learning model may output a dataset based on the extraction. In various embodiments, the system may apply a second machine learning model to the dataset output by the first machine learning model to further extract one or more variables corresponding to the one or more cell features.

Referring to FIG. 5A, the first machine learning model applies a first component analysis to the dataset corresponding to the performance test results of the candidate battery. The first machine learning model extracts a plurality of variables corresponding to an ambient temperature of the battery. For example, in the illustrated embodiment, the plurality of variables is classified into four categories indicative of a fresh battery or an ambient temperature of −10° C., 25° C., and 60° C. Referring to FIG. 5B, the second machine learning model applies a second component analysis to the output of the first machine learning model of FIG. 5A. The second machine learning model extracts a plurality of variables corresponding to the ambient temperature of the battery. For example, in the illustrated embodiment, the plurality of variables extracted by the second machine learning model is classified into four categories further indicative of a fresh battery, a high temperature, a low temperature, and a normal temperature.

Referring to FIG. 5C, the first machine learning model extracts a plurality of variables from the performance test dataset corresponding to a working voltage range of the candidate battery. For example, in the illustrated embodiment, the plurality of variables is classified into five categories indicative of a fresh battery, a range of 0-10%, a range of 0-100%, a range of 25-75%, and a range of 90-100%.

Referring to FIG. 5D, the second machine learning model extracts a plurality of variables from the output of the first machine learning model of FIG. 5C corresponding to the working voltage range of the candidate battery. For example, in the illustrated embodiment, the plurality of variables extracted by the second machine learning model is classified into five categories further indicative of a fresh battery, a range of 0-10%, a range of 0-100%, a range of 25-75%, and a range of 90-100%.

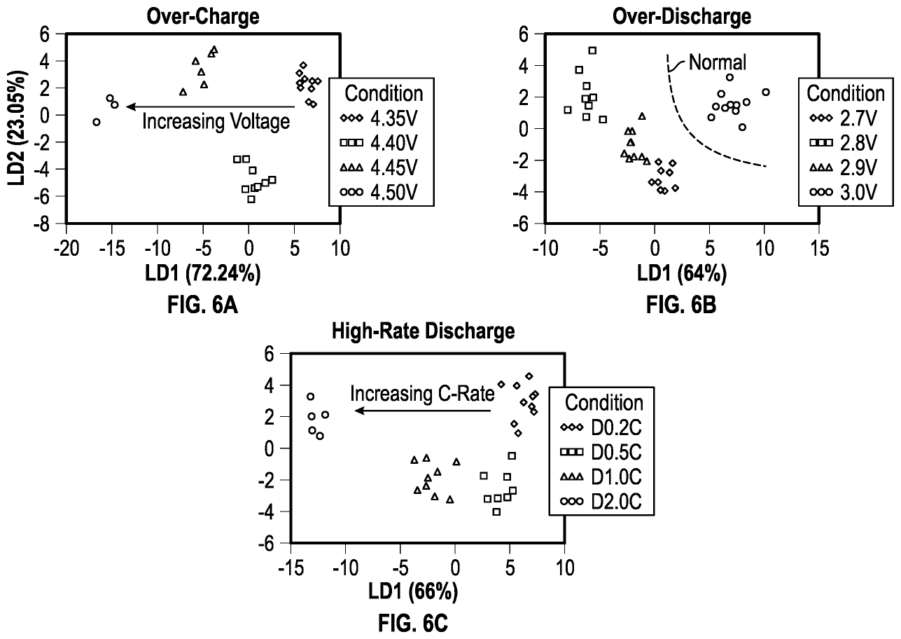

FIGS. 6A-6C illustrates example graphical representations of the one or more cell features of the battery, according to various embodiments. Reference will be made to FIGS. 6A-6C collectively unless specific reference is made otherwise.

The machine learning model applies the one or more models to the performance test data and determines whether each battery includes the one or more cell features indicative of an abuse condition or normal condition operational history aspect. In various embodiments, the machine learning model applies a first modeling set to the performance test data. In various embodiments, the machine learning model further applies a second modeling set to the result of the performance test data and the first model set.

In various embodiments, the machine learning model may determine the one or more cell features of the battery having an unknown operational history aspect. In various embodiments, the machine learning model may output a graphical representation indicative of the one or more cell features. Referring to FIG. 6A, the machine learning model determines that the battery includes an over-charge cell feature indicative of an abuse condition operational history aspect. Each object instance (i.e., variable pair) is graphically plotted by the machine learning model based on the application of the one or more models to the performance test data for each battery. For example, in various embodiments, the machine learning model applies a first model and a second model to the performance test dataset and the machine learning model graphically plots the results of the first and second models representing an over-charge operational history aspect based on the increasing voltage of the battery during cycling. Different groupings of data points in FIG. 6A, for example, represent tested batteries that had different charging or over-charging conditions. For example, different batteries plotted in FIG. 6A were charged to 4.35 V, 4.40 V, 4.45 V, and 4.50 V. This output from a trained machine learning model may therefore identify the batteries that were subject to an over-charge misuse condition (e.g., the 4.50 V over-charged batteries).

Referring to FIG. 6B, the machine learning model determines that the one or more cells for each battery includes an operational history aspect indicative of an over-discharge cell feature. Each object instance pair (i.e., variables) is graphically plotted by the machine learning model based on the application of the one or more models to the performance test data for each battery. For example, in various embodiments, the machine learning model may apply the one or more models to the performance test dataset of a battery and the machine learning model may graphically plot the dataset for the battery representing an over-discharge operational history aspect. Different groupings of data points in FIG. 6B, for example, represent tested batteries that had different discharging or over-discharging conditions. For example, different batteries plotted in FIG. 6B were discharged to 2.7 V, 2.8 V, 2.9 V, and 3.0 V. This output from a trained machine learning model may therefore identify the batteries that were subject to an over-discharge misuse condition (e.g., the 2.7, 2.8, or 2.9 V over-discharged batteries).

Referring to FIG. 6C, the machine learning model determines that the one or more cells for each battery includes an operational history aspect indicative of a high-rate discharge cell feature. Each object instance pairs (i.e., variables) is graphically plotted by the machine learning model based on the application of the one or more models to the performance test dataset for each battery. For example, in various embodiments, the machine learning model may apply the one or more models to the performance test dataset of a battery and the machine learning model may graphically plot the dataset of the battery representing a high-rate discharge operational history aspect based on the increasing C-rate of the battery. As used herein, a C-rate is a measure of the rate at which a battery is discharged relative to its maximum capacity. For example, a 1.0 C rate means that the discharge current will discharge the battery in 1.0 hour. In another example, a 2.0 C rate means the battery will be discharged in 0.5 hours. Different groupings of data points in FIG. 6C, for example, represent tested batteries having different discharge rates (or indicating over-discharge rates). For example, FIG. 6C illustrates graphical data representative of a plurality of batteries having different discharge rates of 0.2 C, 0.5 C, 1.0 C, 2.0 C. Accordingly, the trained machine learning model may identify the batteries demonstrating misuse conditions based on a high discharge rate (e.g., the 2.0 C discharge rate batteries).

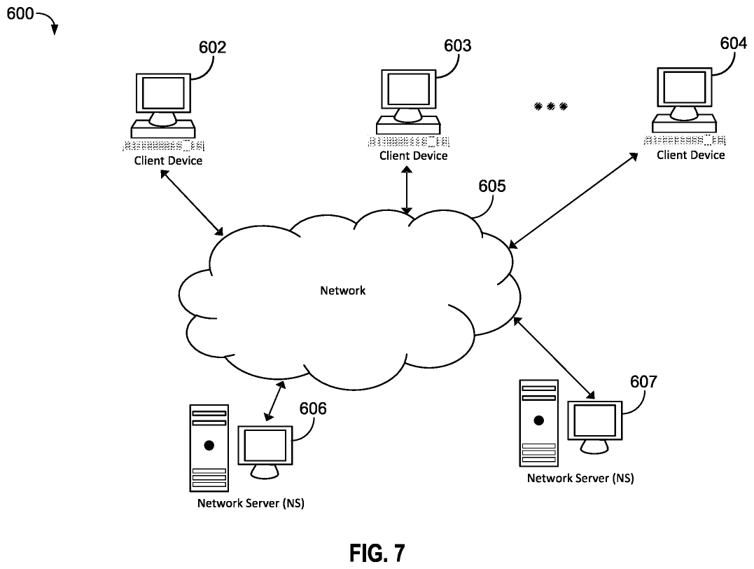

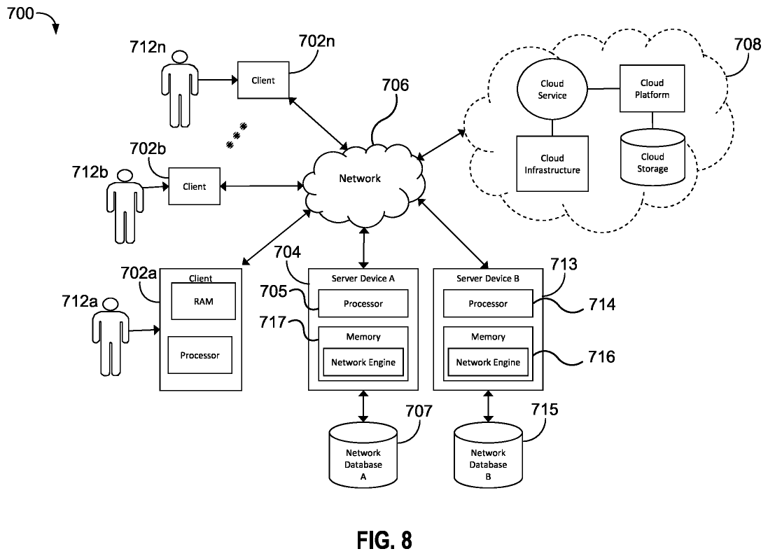

In various embodiments, different aspects are described with respect to FIGS. 7 and 8 that are described in further detail below. Any combination of the various computing components and aspects of FIGS. 7 and 8 may be used in the various embodiments described herein. For example, users may use any of computing devices 602, 603, 604, or 702a through 702n to interact with computing resources or services as described herein, such as to cause a machine learning model to be trained, to analyze batteries, apply machine learning models to identify feature pairs or variables of battery performance tests, apply machine learning models to identify misuse conditions of a battery, train machine learning models with reference datasets to identify misuse conditions of a battery, display aspects described herein on a display, etc. The computing devices 602, 603, 604, or 702a through 702n may communicate with server device 606, 607, 704, or 713; network databases 707 or 715; and/or one or more cloud components 725 through the networks 605 or 706. Any of the server device 606, 607, 704, or 713; the network databases 707 or 715; and/or the one or more cloud components 725 may execute or implement the machine learning models or inference models as described herein to identify or determine operational history aspects of batteries. In various embodiments, the computing devices 602, 603, 604, or 702a through 702n may additionally or alternatively be used to implement or execute the methods or processes described herein. In any event, one or more of the computing devices, systems, etc. may be in communication with any or all of the other devices shown in FIGS. 7 and 8 to implement the systems and methods described herein. For example, an inference model and/or a machine learning model may be implemented/trained on one or more computing devices (e.g., server device 606, 607, 704, or 713; the network databases 707 or 715; cloud components 725), and the machine learning or inference models as described herein may be implemented, stored, retrieved, and/or processed by any of the computing devices and/or the cloud components described herein. The components shown in FIGS. 7 and 8 are described in greater detail below.

In various embodiments, exemplary inventive, specially programmed computing systems/platforms with associated devices are configured to operate in the distributed network environment, communicating with one another over one or more suitable data communication networks (e.g., the Internet, satellite, etc.) and utilizing one or more suitable data communication protocols/modes such as, without limitation, IPX/SPX, X.25, AX.25, AppleTalk™, TCP/IP (e.g., HTTP), Bluetooth™, near-field wireless communication (NFC), RFID, Narrow Band Internet of Things (NBIOT), 3G, 4G, 5G, GSM, GPRS, WiFi, WiMax, CDMA, satellite, ZigBee, and other suitable communication modes.

The material disclosed herein may be implemented in software or firmware or a combination of them or as instructions stored on a machine-readable medium, which may be read and executed by one or more processors. A machine-readable medium may include any medium and/or mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others.

The aforementioned examples are, of course, illustrative and not restrictive.

As used herein, the term “user” shall have a meaning of at least one user. In various embodiments, the terms “user”, “subscriber” “consumer” or “customer” should be understood to refer to a user of an application or applications as described herein, and/or a consumer of data supplied by a data provider. By way of example, and not limitation, the terms “user” or “subscriber” can refer to a person who receives data provided by the data or service provider over the Internet in a browser session or can refer to an automated software application which receives the data and stores or processes the data.

FIG. 7 is a block diagram depicting a computer-based system and platform, according to various embodiments. However, not all of these components may be required to practice one or more embodiments, and variations in the arrangement and type of the components may be made without departing from the spirit or scope of various embodiments of the present disclosure. In various embodiments, the exemplary inventive computing devices and/or the exemplary inventive computing components of the exemplary computer-based system/platform 600 may be configured to manage a large number of members and/or concurrent transactions, as detailed herein. In various embodiments, the exemplary computer-based system/platform 600 may be based on a scalable computer and/or network architecture that incorporates varies strategies for assessing the data, caching, searching, and/or database connection pooling. An example of the scalable architecture is an architecture that is capable of operating multiple servers.

In various embodiments, referring to FIG. 7, members 602-604 (e.g., clients) of the exemplary computer-based system/platform 600 may include virtually any computing device capable of receiving and sending a message over a network (e.g., cloud network), such as network 605, to and from another computing device, such as server device 606 and 607, each other, and the like. In various embodiments, the member devices 602-604 may be personal computers, multiprocessor systems, microprocessor-based or programmable consumer electronics, network PCs, and the like. In various embodiments, one or more member devices within member devices 602-604 may include computing devices that typically connect using a wireless communications medium such as cell phones, smart phones, pagers, walkie talkies, radio frequency (RF) devices, infrared (IR) devices, CBs, integrated devices combining one or more of the preceding devices, or virtually any mobile computing device, and the like. In various embodiments, one or more member devices within member devices 102-104 may be devices that are capable of connecting using a wired or wireless communication medium such as a PDA, POCKET PC, wearable computer, a laptop, tablet, desktop computer, a netbook, a video game device, a pager, a smart phone, an ultra-mobile personal computer (UMPC), and/or any other device that is equipped to communicate over a wired and/or wireless communication medium (e.g., NFC, RFID, NBIOT, 3G, 4G, 5G, GSM, GPRS, WiFi, WiMax, CDMA, satellite, ZigBee, etc.). In various embodiments, one or more member devices within member devices 602-604 may include may run one or more applications, such as Internet browsers, mobile applications, voice calls, video games, videoconferencing, and email, among others. In various embodiments, one or more member devices within member devices 602-604 may be configured to receive and to send web pages, and the like. In various embodiments, an exemplary specifically programmed browser application of the present disclosure may be configured to receive and display graphics, text, multimedia, and the like, employing virtually any web based language, including, but not limited to Standard Generalized Markup Language (SMGL), such as HyperText Markup Language (HTML), a wireless application protocol (WAP), a Handheld Device Markup Language (HDML), such as Wireless Markup Language (WML), WMLScript, XML, JavaScript, and the like. In various embodiments, a member device within member devices 102-104 may be specifically programmed by either Java, .Net, QT, C, C++ and/or other suitable programming language. In various embodiments, one or more member devices within member devices 102-104 may be specifically programmed include or execute an application to perform a variety of possible tasks, such as, without limitation, messaging functionality, browsing, searching, playing, streaming or displaying various forms of content, including locally stored or uploaded messages, images and/or video, and/or games.

In various embodiments, the network 605 may provide network access, data transport and/or other services to any computing device coupled to it. In various embodiments, the network 605 may include and implement at least one specialized network architecture that may be based at least in part on one or more standards set by, for example, without limitation, Global System for Mobile communication (GSM) Association, the Internet Engineering Task Force (IETF), and the Worldwide Interoperability for Microwave Access (WiMAX) forum. In various embodiments, the network 105 may implement one or more of a GSM architecture, a General Packet Radio Service (GPRS) architecture, a Universal Mobile Telecommunications System (UMTS) architecture, and an evolution of UMTS referred to as Long Term Evolution (LTE). In various embodiments, the network 105 may include and implement, as an alternative or in conjunction with one or more of the above, a WiMAX architecture defined by the WiMAX forum. In various embodiments and, optionally, in combination of any embodiment described above or below, the network 105 may also include, for instance, at least one of a local area network (LAN), a wide area network (WAN), the Internet, a virtual LAN (VLAN), an enterprise LAN, a layer 3 virtual private network (VPN), an enterprise IP network, or any combination thereof. In various embodiments and, optionally, in combination of any embodiment described above or below, at least one computer network communication over the network 105 may be transmitted based at least in part on one of more communication modes such as but not limited to: NFC, RFID, Narrow Band Internet of Things (NBIOT), ZigBee, 3G, 4G, 5G, GSM, GPRS, WiFi, WiMax, CDMA, satellite and any combination thereof. In various embodiments, the network 105 may also include mass storage, such as network attached storage (NAS), a storage area network (SAN), a content delivery network (CDN) or other forms of computer or machine readable media.

In various embodiments, the server device 606 or the server device 607 may be a web server (or a series of servers) running a network operating system, examples of which may include but are not limited to Microsoft Windows Server, Novell NetWare, or Linux. In various embodiments, the server device 606 or the exemplary server device 607 may be used for and/or provide cloud and/or network computing. Although not shown in FIG. 7, in various embodiments, the server device 606 or the server device 607 may have connections to external systems like email, SMS messaging, text messaging, ad content providers, etc. Any of the features of the server device 606 may be also implemented in the server device 607 and vice versa.

In various embodiments, one or more of the server devices 606 and 607 may be specifically programmed to perform, in non-limiting example, as authentication servers, search servers, email servers, social networking services servers, SMS servers, IM servers, MMS servers, exchange servers, photo-sharing services servers, advertisement providing servers, financial/banking-related services servers, travel services servers, or any similarly suitable service-base servers for users of the computing devices 601-604.

In various embodiments and, optionally, in combination of any embodiment described above or below, for example, one or more computing devices 602-604, the server device 606, and/or the server device 607 may include a specifically programmed software module that may be configured to send, process, and receive information using a scripting language, a remote procedure call, an email, a tweet, Short Message Service (SMS), Multimedia Message Service (MMS), instant messaging (IM), internet relay chat (IRC), mIRC, Jabber, an application programming interface, Simple Object Access Protocol (SOAP) methods, Common Object Request Broker Architecture (CORBA), HTTP (Hypertext Transfer Protocol), REST (Representational State Transfer), or any combination thereof.

FIG. 8 depicts a block diagram of another exemplary computer-based system/platform 700 in accordance with one or more embodiments of the present disclosure. However, not all of these components may be required to practice one or more embodiments, and variations in the arrangement and type of the components may be made without departing from the spirit or scope of various embodiments of the present disclosure. In various embodiments, the computing devices 702a, 702b through 702n shown each at least include a computer-readable medium, such as a random-access memory (RAM) coupled to a processor 710 or FLASH memory. In various embodiments, the processor 710 may execute computer-executable program instructions stored in memory 708. In various embodiments, the processor 710 may include a microprocessor, an ASIC, and/or a state machine. In various embodiments, the processor 710 may include, or may be in communication with, media, for example computer-readable media, which stores instructions that, when executed by the processor 710, may cause the processor 710 to perform one or more steps described herein. In various embodiments, examples of computer-readable media may include, but are not limited to, an electronic, optical, magnetic, or other storage or transmission device capable of providing a processor, such as the processor 710 of client 702a, with computer-readable instructions. In various embodiments, other examples of suitable media may include, but are not limited to, a floppy disk, CD-ROM, DVD, magnetic disk, memory chip, ROM, RAM, an ASIC, a configured processor, all optical media, all magnetic tape or other magnetic media, or any other medium from which a computer processor can read instructions. Also, various other forms of computer-readable media may transmit or carry instructions to a computer, including a router, private or public network, or other transmission device or channel, both wired and wireless. In various embodiments, the instructions may comprise code from any computer-programming language, including, for example, C, C++, Visual Basic, Java, Python, Perl, JavaScript, and etc.

In various embodiments, computing devices 702a through 702n may also include a number of external or internal devices such as a mouse, a CD-ROM, DVD, a physical or virtual keyboard, a display, or other input or output devices. In various embodiments, examples of computing devices 702a through 702n (e.g., clients) may be any type of processor-based platforms that are connected to a network 706 such as, without limitation, personal computers, digital assistants, personal digital assistants, smart phones, pagers, digital tablets, laptop computers, Internet appliances, and other processor-based devices. In various embodiments, computing devices 702a through 702n may be specifically programmed with one or more application programs in accordance with one or more principles/methodologies detailed herein. In various embodiments, computing devices 702a through 702n may operate on any operating system capable of supporting a browser or browser-enabled application, such as Microsoft™, Windows™, and/or Linux. In various embodiments, computing devices 702a through 702n shown may include, for example, personal computers executing a browser application program such as Microsoft Corporation's Internet Explorer™, Apple Computer, Inc.'s Safari™, Mozilla Firefox, and/or Opera. In various embodiments, through the computing devices 702a through 702n, users 712a through 712n may communicate over the network 706 with each other and/or with other systems and/or devices coupled to the network 706. As shown in FIG. 8, server devices 704 and 713 may be also coupled to the network 706. In various embodiments, one or more computing devices 702a through 702n may be mobile clients.

In various embodiments, at least one database of network databases 707 and 715 may be any type of database, including a database managed by a database management system (DBMS). In various embodiments, an exemplary DBMS-managed database may be specifically programmed as an engine that controls organization, storage, management, and/or retrieval of data in the respective database. In various embodiments, the exemplary DBMS-managed database may be specifically programmed to provide the ability to query, backup and replicate, enforce rules, provide security, compute, perform change and access logging, and/or automate optimization. In various embodiments, the exemplary DBMS-managed database may be chosen from Oracle database, IBM DB2, Adaptive Server Enterprise, FileMaker, Microsoft Access, Microsoft SQL Server, MySQL, PostgreSQL, and a NoSQL implementation. In various embodiments, the exemplary DBMS-managed database may be specifically programmed to define each respective schema of each database in the exemplary DBMS, according to a particular database model of the present disclosure which may include a hierarchical model, network model, relational model, object model, or some other suitable organization that may result in one or more applicable data structures that may include fields, records, files, and/or objects. In various embodiments, the exemplary DBMS-managed database may be specifically programmed to include metadata about the data that is stored.

As also shown in FIG. 8, various embodiments of the disclosed technology may also include and/or involve one or more cloud components 725, which are shown grouped together in the drawing for sake of illustration, though may be distributed in various ways as known in the art. Cloud components 725 may include one or more cloud services such as software applications (e.g., queue, etc.), one or more cloud platforms (e.g., a Web front-end, etc.), cloud infrastructure (e.g., virtual machines, etc.), and/or cloud storage (e.g., cloud databases, etc.).

According to various embodiments, the exemplary inventive computer-based systems/platforms, the exemplary inventive computer-based devices, components and media, and/or the exemplary inventive computer-implemented methods of the present disclosure may be specifically configured to operate in or with cloud computing/architecture such as, but not limiting to: infrastructure a service (laaS), platform as a service (PaaS), and/or software as a service (SaaS).

As used herein, the terms “computer engine” and “engine” identify at least one software component and/or a combination of at least one software component and at least one hardware component which are designed/programmed/configured to manage/control other software and/or hardware components (such as the libraries, software development kits (SDKs), objects, etc.).

Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. In various embodiments, the one or more processors may be implemented as a Complex Instruction Set Computer (CISC) or Reduced Instruction Set Computer (RISC) processors; x86 instruction set compatible processors, multi-core, or any other microprocessor or central processing unit (CPU). In various implementations, the one or more processors may be dual-core processor(s), dual-core mobile processor(s), and so forth.

Examples of software may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

One or more aspects of at least one embodiment may be implemented by representative instructions stored on a machine-readable medium which represents various logic within the processor, which when read by a machine causes the machine to fabricate logic to perform the techniques described herein. Such representations, known as “IP cores,” may be stored on a tangible, machine readable medium and supplied to various customers or manufacturing facilities to load into the fabrication machines that make the logic or processor. Of note, various embodiments described herein may, of course, be implemented using any appropriate hardware and/or computing software languages (e.g., C++, Objective-C, Swift, Java, JavaScript, Python, Perl, QT, etc.).

In various embodiments, one or more of exemplary inventive computer-based systems/platforms, exemplary inventive computer-based devices, and/or exemplary inventive computer-based components of the present disclosure may include or be incorporated, partially or entirely into at least one personal computer (PC), laptop computer, ultra-laptop computer, tablet, touch pad, portable computer, handheld computer, palmtop computer, personal digital assistant (PDA), cellular telephone, combination cellular telephone/PDA, television, smart device (e.g., smart phone, smart tablet or smart television), mobile internet device (MID), messaging device, data communication device, and so forth.

As used herein, the term “server” should be understood to refer to a service point which provides processing, database, and communication facilities. By way of example, and not limitation, the term “server” can refer to a single, physical processor with associated communications and data storage and database facilities, or it can refer to a networked or clustered complex of processors and associated network and storage devices, as well as operating software and one or more database systems and application software that support the services provided by the server. Cloud components and cloud servers are examples.

In various embodiments, as detailed herein, one or more of the computer-based systems of the present disclosure may obtain, manipulate, transfer, store, transform, generate, and/or output any digital object and/or data unit (e.g., from inside and/or outside of a particular application) that can be in any suitable form such as, without limitation, a file, a contact, a task, an email, a message, a map, an entire application (e.g., a calculator), data points, and other suitable data. In various embodiments, as detailed herein, one or more of the computer-based systems of the present disclosure may be implemented across one or more of various computer platforms such as, but not limited to: (1) Linux™, (2) Microsoft Windows™, (3) OS X (Mac OS), (4) Solaris™, (5) UNIX™ (6) VMWare™, (7) Android™, (8) Java Platforms™, (9) Open Web Platform, (10) Kubernetes or other suitable computer platforms. In various embodiments, illustrative computer-based systems or platforms of the present disclosure may be configured to utilize hardwired circuitry that may be used in place of or in combination with software instructions to implement features consistent with principles of the disclosure. Thus, implementations consistent with principles of the disclosure are not limited to any specific combination of hardware circuitry and software. For example, various embodiments may be embodied in many different ways as a software component such as, without limitation, a stand-alone software package, a combination of software packages, or it may be a software package incorporated as a “tool” in a larger software product.

For example, exemplary software specifically programmed in accordance with one or more principles of the present disclosure may be downloadable from a network, for example, a website, as a stand-alone product or as an add-in package for installation in an existing software application. For example, exemplary software specifically programmed in accordance with one or more principles of the present disclosure may also be available as a client-server software application, or as a web-enabled software application. For example, exemplary software specifically programmed in accordance with one or more principles of the present disclosure may also be embodied as a software package installed on a hardware device.

In various embodiments, exemplary inventive computer-based systems/platforms, exemplary inventive computer-based devices, and/or exemplary inventive computer-based components of the present disclosure may be configured to output to distinct, specifically programmed graphical user interface implementations of the present disclosure (e.g., a desktop, a web app., etc.). In various implementations of the present disclosure, a final output may be displayed on a displaying screen which may be, without limitation, a screen of a computer, a screen of a mobile device, or the like. In various implementations, the display may be a holographic display. In various implementations, the display may be a transparent surface that may receive a visual projection. Such projections may convey various forms of information, images, and/or objects. For example, such projections may be a visual overlay for a mobile augmented reality (MAR) application.

In various embodiments, exemplary inventive computer-based systems/platforms, exemplary inventive computer-based devices, and/or exemplary inventive computer-based components of the present disclosure may be configured to be utilized in various applications which may include, but not limited to, gaming, mobile-device games, video chats, video conferences, live video streaming, video streaming and/or augmented reality applications, mobile-device messenger applications, and others similarly suitable computer-device applications.

In various embodiments, the exemplary inventive computer-based systems/platforms, the exemplary inventive computer-based devices, and/or the exemplary inventive computer-based components of the present disclosure may be configured to securely store and/or transmit data by utilizing one or more of encryption techniques (e.g., private/public key pair, Triple Data Encryption Standard (3DES), block cipher algorithms (e.g., IDEA, RC2, RC5, CAST and Skipjack), cryptographic hash algorithms (e.g., MD5, RIPEMD-160, RTR0, SHA-1, SHA-2, Tiger (TTH), WHIRLPOOL, RNGs).

All prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in various embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “between” does not necessarily require being disposed directly next to other elements. Generally, this term means a configuration where something is sandwiched by two or more other things. At the same time, the term “between” can describe something that is directly next to two opposing things. Accordingly, in any one or more of the embodiments disclosed herein, a particular structural component being disposed between two other structural elements can be: disposed directly between both of the two other structural elements such that the particular structural component is in direct contact with both of the two other structural elements; disposed directly next to only one of the two other structural elements such that the particular structural component is in direct contact with only one of the two other structural elements; disposed indirectly next to only one of the two other structural elements such that the particular structural component is not in direct contact with only one of the two other structural elements, and there is another element which juxtaposes the particular structural component and the one of the two other structural elements; disposed indirectly between both of the two other structural elements such that the particular structural component is not in direct contact with both of the two other structural elements, and other features can be disposed therebetween; or any combination(s) thereof.

What is claimed is:

1. A method comprising:
determining, by one or more processors of one or more computing devices, a first dataset based on a cycle of one or more cells of a battery;
extracting, by the one or more processors by applying a first model to the first dataset, a second dataset comprising variables associated with the cycle of the one or more cells of the battery;
extracting, by the one or more processors, a third dataset based on applying a second model to the second dataset, wherein the second model is trained using a plurality of reference datasets associated with a plurality of battery cells, each of the plurality of reference datasets annotated with at least one cell feature or reference operational history aspects; and
determining, by the one or more processors, an operational history aspect indicative of the at least one cell feature of the battery extracted based on applying the second model to the third dataset.

2. The method according to claim 1, wherein the first dataset comprises a plurality of first feature pairs indicative of an unknown operation history, the second dataset comprises a plurality of second feature pairs for the at least one cell feature, and the third dataset comprises a plurality of third feature pairs.

3. The method according to claim 2, wherein extracting the second dataset based on applying the first model to the first dataset further comprises:
extracting, by the one or more processors, the plurality of second feature pairs based on a principal component analysis including an unsupervised algorithm of the first dataset for the at least one cell feature.

4. The method according to claim 3, wherein each feature pair of the plurality of second feature pairs comprises:
a first vector based on a respective first feature pair of the plurality of first feature pairs and a first eigenvalue corresponding to the respective first feature pair, and
a second vector based on the respective first feature pair and a second eigenvalue corresponding to the respective first feature pair.

5. The method according to claim 2, wherein extracting the third dataset based on applying the second model to the second dataset further comprises:
extracting, by the one or more processors, the plurality of third feature pairs based on a linear discriminant analysis including a supervised algorithm of the second dataset for the at least one cell feature.

6. The method according to claim 5, wherein each feature pair of the plurality of third feature pairs comprises:
a third vector based on a respective second feature pair of the plurality of second feature pairs and a third eigenvalue corresponding to the respective second feature pair, and
a fourth vector based on the respective second feature pair and a fourth eigenvalue corresponding to the respective second feature pair.

7. The method according to claim 2, wherein each respective first feature pair of the plurality of first feature pairs comprises a voltage and a capacity of the one or more cells over a voltage range of the cycle from a first voltage to a second voltage.

8. The method according to claim 7, further comprising:
determining, by the one or more processors, a fourth dataset based on the first dataset, wherein the fourth dataset comprises a plurality of fourth feature pairs for the at least one cell feature;
wherein each respective fourth feature pair of the plurality of fourth feature pairs comprises a mean voltage and a dQ-dV of the battery of the one or more cells over the voltage range of the cycle.

9. The method according to claim 1, further comprising:
training, by the one or more processors, the first model and the second model based on a training dataset; and
training, by the one or more processors, the plurality of reference datasets based on the training dataset;
wherein each reference dataset is indicative of results of a reference principal component analysis performed by the first model and a reference linear discriminate analysis performed by the second model to determine the at least one cell feature.

10. The method according to claim 2, wherein each reference dataset of the plurality of reference datasets further comprises a plurality of historical feature pairs annotated with a cell feature of the at least one cell feature.

11. The method according to claim 1, wherein the at least one cell feature comprises one of:
a normal operation,
an ambient temperature,
a working voltage range,
a high-rate discharge parameter, or
an abnormal operation voltage range.

12. A system comprising:
at least one processor; and
a non-transitory computer readable medium having instructions stored thereon that, when executed by the at least one processor, cause the system to perform operations comprising:
determine a first dataset based on a cycle of one or more cells of a battery having an unknown operation history;
extract, based on applying a first model to the first dataset, a second dataset comprising variables associated with the cycle of the one or more cells of the battery;
extract a third dataset based on applying a second model to the second dataset, wherein the second model is trained using a plurality of reference datasets associated with a plurality of battery cells, each of the plurality of reference datasets annotated with at least one cell feature or reference operational history aspects;
determine an operational history aspect indicative of the at least one cell feature of the battery extracted based on applying the second model to the third dataset; and
send data to a display indicative of the operational history aspect of the battery.

13. The system according to claim 12, wherein the first dataset comprises a plurality of first feature pairs indicative of the unknown operation history, the second dataset comprises a plurality of second feature pairs for the at least one cell feature, and the third dataset comprises a plurality of third feature pairs.

14. The system according to claim 13, wherein the data sent to the display is indicative of the third dataset matching the plurality of reference datasets.

15. The system according to claim 14, wherein the data sent to the display further comprises scatter plot data configured to cause the display to show a representation of the third dataset;
wherein the third dataset is indicative of a linear discriminant analysis including a supervised algorithm for the at least one cell feature.

16. The system according to claim 13, further comprising:
determine a fourth dataset based on the first dataset, wherein the fourth dataset includes a plurality of fourth feature pairs for the at least one cell feature;
wherein each respective first feature pair of the plurality of first feature pairs comprises a voltage and a capacity of the one or more cells over a voltage range of the cycle from a first voltage to a second voltage; and
wherein each respective fourth feature pair of the plurality of fourth feature pairs comprises a mean voltage and a dQ-dV of the battery of the one or more cells over the voltage range of the cycle.

17. The system according to claim 13, wherein each respective second feature pair of the plurality of second feature pairs comprises:
a first vector based on a respective first feature pair of the plurality of first feature pairs and a first eigenvalue corresponding to the respective first feature pair, and
a second vector based on the respective first feature pair and a second eigenvalue corresponding to the respective first feature pair;
wherein each respective third feature pair of the plurality of third feature pairs comprises:
a third vector based on a respective second feature pair of the plurality of second feature pairs and a third eigenvalue corresponding to the respective second feature pair, and
a fourth vector based on the respective second feature pair and a fourth eigenvalue corresponding to the respective second feature pair.

18. The system according to claim 13, wherein the at least one cell feature comprises one of:
a normal operation,
an ambient temperature,
a working voltage range,
a high-rate discharge parameter, or
an abnormal operation voltage range.

19. The system according to claim 13, further comprising:
train the first model and the second model based on a training dataset; and
train the plurality of reference datasets based on the training dataset;
wherein each reference dataset is indicative of results of a reference principal component analysis performed by the first model and a reference linear discriminant analysis performed by the second model to determine the at least one cell feature.

20. A non-transitory computer readable medium having instructions stored thereon that, when executed by a computing device, cause the computing device to perform operations comprising:
receive a plurality of reference datasets annotated with a cell feature of at least one cell feature;
determine a first dataset based on a cycle of one or more cells of a battery, wherein the first dataset comprises a plurality of first feature pairs indicative of an unknown operation history;
extract a second dataset including a plurality of second feature pairs based on applying a first model to the first dataset, wherein the plurality of second feature pairs comprises:
a first vector based on a respective second feature pair of the plurality of second feature pairs and a first eigenvalue corresponding to the respective second feature pair, and
a second vector based on the respective second feature pair and a second eigenvalue corresponding to the respective second feature pair;
extract a third dataset including a plurality of third feature pairs based on applying a second model to the second dataset, wherein the plurality of third feature pairs comprises:
a third vector based on a respective third feature pair of the plurality of third feature pairs and a third eigenvalue corresponding to the respective third feature pair, and
a fourth vector based on the respective third feature pair and a fourth eigenvalue corresponding to the respective third feature pair; and
determine an operational history aspect of the battery extracted based on applying the second model and the third dataset;
wherein the at least one cell feature comprises one of:
a normal operation,
an ambient temperature,
a working voltage range,
a high-rate discharge parameter, or
an abnormal operation voltage range.

21. The non-transitory computer readable medium of claim 20, wherein the computing device performs operations further comprising:
determine a fourth dataset based on the first dataset, wherein the fourth dataset includes a plurality of fourth feature pairs for a respective cell feature;
wherein each of the plurality of first feature pairs comprises a voltage and a capacity of the one or more cells over a voltage range of the cycle from a first voltage to a second voltage; and
wherein each of the plurality of fourth feature pairs comprises a mean voltage and a dQ-dV of the battery of the one or more cells over the voltage range of the cycle.

22. The non-transitory computer readable medium of claim 20, further comprising:
train the first model and the second model based on a training dataset; and
train the plurality of reference datasets based on the training dataset;
wherein each reference dataset is indicative of results of a reference principal component analysis performed by the first model and a reference linear discriminate analysis performed by the second model to determine the at least one cell feature.
